(19) United States
(12) Patent Application Publication
(10) Pub. No.: US 2008/0007901 A1
(43) Pub. Date: Jan. 10, 2008

(54) PORTABLE ELECTRONIC DEVICE HAVING COUPLER CONNECTING TWO PANELS

(75) Inventors: YOUNG-SOO HAN, ANYANG-SI (KR); JONG-WOONG KANG, SUWON-SI (KR); SEUNG-HEE CHO, HWASEONG-SI (KR)

Correspondence Address: KNOBBE MARTENS OLSON & BEAR LLP, 2040 MAIN STREET, FOURTEENTH FLOOR, IRVINE, CA, 92614, US

(73) Assignee: PHOENIX KOREA CO., LTD., HWASEONG-SI (KR)

(21) Appl. No.: 11/768,826

(22) Filed: Jun. 26, 2007

Related U.S. Application Data
(63) Continuation-in-part of application No. PCT/KR05/04552, filed on Dec. 26, 2005.

(30) Foreign Application Priority Data
Dec. 27, 2004 (KR) 10-2004-0112993

(51) Int. Cl. H05K 7/00

(52) U.S. Cl. 361/679

(57) ABSTRACT

Disclosed is a coupling device for coupling first and second units with each other in a portable apparatus in which the first and second units are folded or unfolded with respect to each other about a first rotation axis. The coupling device includes first and second supporting bodies coupled with each other to be relatively rotated about the first rotation axis and to be folded or unfolded with respect to each other. The coupling device further includes a first rotating member coupled with the first supporting body to be relatively rotated with respect to the first supporting body about a second rotation axis The coupling device comprises a second rotating member coupled with the second supporting body to be relatively rotated with respect to the second supporting body about a third rotation axis.

### CROSS-REFERENCE TO RELATED PATENT APPLICATIONS

This application is a continuation-in-part application under 35 U.S.C. § 365(c) of International Application No. PCT/KR2005/004552, filed Dec. 26, 2005 designating the United States. International Application No. PCT/KR2005/004552 was published in English as WO2006/071040 A1 on Jul. 6, 2006. This application further claims the benefit of the earlier filing dates under 35 U.S.C. § 365(b) of Korean Patent Application No. 10-2004-0112993 filed Dec. 27, 2004. This application incorporates herein by reference the International Application No. PCT/KR2005/004552 including the International Publication No. WO2006/071040 A1 and the Korean Patent Application No. 10-2004-0112993 in their entirety.

### BACKGROUND

1. Field

The present disclosure relates to a portable device, and more particularly, portable electronic device e.g., a mobile telephone, a PDA, a portable computer or the like.

2. Description of Related Technology

A portable apparatus such as a portable folder-type telephone includes two case units coupled with each other by means of a hinge device. Typically, one of the case units is provided with a keypad with buttons and the other one is provided with a liquid crystal display. When the telephone is in use, the keypad and the display are unfolded so that they can be accessed from the outside. The hinge device allows the two case units to be coupled with each other and to be smoothly folded (closed) or unfolded (flip opened) with respect to each other.

An exemplary hinge device is constructed as follows. The hinge device comprises a rotating member, a linearly moving member, a resilient member, and a housing. The housing contains the rotating member, the linearly moving member and the resilient member. The rotating member can rotate about a rotation axis within the housing and a portion of the rotating member including the rotation axis protrudes outside of the housing to form a coupling portion. The linearly moving member is in contact with the rotating member and cannot rotate within the housing but moves linearly along the rotation axis of the housing. The resilient member applies a force so that the linearly moving member and the rotating member can be brought into close contact with each other within the housing. At this time, the contact surfaces of the linearly moving member and the rotating member are properly configured such that the rotating member may easily rotate even without an external force within a certain range and may be well maintained in a stationary state at a predetermined location.

One of the two case units of the portable telephone that are intended to be coupled with the hinge device constructed as above is fixed to the housing while the other is fixed to the coupling portion of the rotating member. If the two case units connected as above are under a folded state or an unfolded state by means of the operation of the hinge device, the case units of the portable telephone cannot be rotated with each other. Furthermore, in order to fold the two units from an unfolded state or unfold them from a folded state, it is necessary for a user to use his/her hand to initially apply an external force to the units. Generally, the two units are constructed to be automatically folded or unfolded after such a range.

The foregoing discussion in this section is to provide general background information, and does not constitute an admission of prior art.

### SUMMARY

One aspect of the invention provides a portable electronic device, comprising: a first panel; a second panel; and a connector connecting the first panel and second panel, the connector comprising a first piece and a second piece connected to the first piece, wherein the second piece is rotatable relative to the first piece about a first axis, wherein the first piece is connected to the first panel, the first panel being rotatable relative to the first piece about a second axis, wherein the second piece is connected to the second panel, the second panel being rotatable relative to the second piece about a third axis.

In the foregoing device, the second piece may be connected to the second panel such that the second panel is rotatable relative to the first piece about the first axis. At least one of the second axis and the third second axis may be substantially perpendicular to the first axis. The connector may be configured to enable the first and second panels to move relative to each other between a folded configuration and a first unfolded configuration and further between the first unfolded configuration and a second unfolded configuration, wherein between the first and second unfolded configurations, at least one of the first and second panels is configured to rotate about the second or third axis. Between the first and second unfolded configurations, both the first and second panels may be configured to rotate about the second or third axis. In the folded configuration, the second axis substantially may overlap with the third axis, wherein the connector may be further configured to allow the first panel to rotate about the second axis relative to the connector from the folded configuration. In the folded configuration, the first and second pieces may be overlapping with each other, wherein the connector may be further configured to allow the first piece and second piece rotate about the second axis relative to each other.

Still in the foregoing device, the first panel may comprise a substantially flat display surface for displaying information thereon, wherein the second panel may comprise a substantially flat input surface comprising a plurality of buttons for inputting alphanumeric information therethrough, wherein in the folded configuration, the display surface and the input surface may face each other. The first panel may comprise a first edge extending generally straight, and the second panel may comprise a second edge extending generally straight, wherein in the folded configuration, the first edge and the second edge may be generally overlapping when viewed away from the device in a direction perpendicular to the display surface, wherein in the first unfolded configuration, the first edge and the second edge may extend generally in the same direction without overlapping when viewed away from the device in the direction perpendicular to the display surface. In the second unfolded configuration, the first edge and second edge may extend generally in the same direction opposing each other when viewed away from the device in the direction perpendicular to the display surface.

Further in the foregoing device, the third axis may be substantially parallel to the second axis. The third axis may be substantially nonparallel to the second axis. The first panel may comprise a first surface, wherein the second panel may comprise a second surface, wherein the first and second surfaces may oppose each other in the folded configuration, wherein in the first unfolded configuration, the first and second surfaces may form an angle therebetween from about 120° to about 200°. The portable device may comprise a handheld electronic device.

Another aspect of the invention provides a method of changing configurations of a portable electronic device, comprising: providing the foregoing portable electronic device, the device comprising a first panel, a second panel and a connector interconnecting the first and second panels; moving the first and second panels relative to each other between a folded configuration and a first unfolded configuration; and moving the first and second panels relative to each other between the first unfolded configuration and a second unfolded configuration.

Still another aspect of the invention provides a portable electronic device, comprising: a first panel; a second panel; and a first hinge configured to enable the first and second panels to move relative to each other between a folded configuration and a first unfolded configuration; a second hinge configured to enable the first and second panels to move relative to each other between the first unfolded configuration and a second unfolded configuration; and a third hinge configured to enable the first and second panels to move relative to each other between the second unfolded configuration and a third unfolded configuration.

In the foregoing device, the first, second and third hinges may form a self-contained connector. The connector may comprise a first piece and a second piece connected to the first piece, wherein the first hinge may be configured to enable to move the first piece and the second piece with respect to each other. The first panel may comprise a substantially flat display surface for displaying information thereon, wherein the second panel may comprise a substantially flat input surface comprising a plurality of buttons for inputting alphanumeric information therethrough, wherein in the folded configuration, the display surface and the input surface may face each other. In the folded configuration, the display surface and the input surface may form therebetween an angle, which is substantially equal to 0°. In the first unfolded configuration, the display surface and the input surface may form an angle therebetween, which is from about from about 120° to about 200°. In the first and second unfolded configurations, the display surface and the input surface may form an angle therebetween, which is from about 120° to about 200°.

Still in the foregoing device, the first panel may comprise a first edge extending generally straight, and the second panel may comprise a second edge extending generally straight, wherein in the folded configuration the first edge and the second edge may be generally overlapping, wherein in the first unfolded configuration, the first edge and the second edge may extend generally in the same direction without overlapping when viewed away from the device in a direction perpendicular to the display surface. In the third unfolded configuration, the first edge and second edge may extend generally in the same direction opposing each other when viewed away from the device in the direction perpendicular to the display surface. The first panel may comprise a first edge extending generally straight, and the second panel may comprise a second edge extending generally straight, wherein in the folded configuration the first edge and the second edge are generally overlapping, wherein in the first unfolded configuration, the first edge and the second edge may form therebetween a first angle of about 160° to about 200°, when viewed away from the device in the direction perpendicular to the display surface. In the third unfolded configuration, the first edge and the second edge may form therebetween a third angle of 0° to about 90°, when viewed away from the device in the direction perpendicular to the display surface. In the second unfolded configuration, the first edge and the second edge may form therebetween a second angle between the first and second angle, when viewed away from the device in the direction perpendicular to the display surface.

An aspect of the present invention provides a portable apparatus having two units that may be folded or unfolded in various directions and a coupling device for coupling the units of the apparatus.

Another aspect of the present invention provides a coupling device for coupling two units with each other so that the units can be controlled at various angles therebetween in a portable apparatus in which the units are folded or unfolded with respect to each other.

A further aspect of the present invention provides a portable apparatus having a liquid crystal display, wherein the liquid crystal display can be controlled in various directions.

An aspect of the present invention provides a coupling device for coupling first and second units with each other in a portable apparatus in which the first and second units are folded or unfolded with respect to each other about a first rotation axis, wherein the coupling device comprises first and second supporting bodies coupled with each other to be relatively rotated about the first rotation axis and to be folded or unfolded with respect to each other; a first rotating member coupled with the first supporting body to be relatively rotated with respect to the first supporting body about a second rotation axis substantially perpendicular to opposing surfaces of the two units facing to each other when the two units are folded with respect to each other, and coupled with the first unit so that the first rotating member and the first unit can be rotated together about the second rotation axis; and a second rotating member coupled with the second supporting body to be relatively rotated with respect to the second supporting body about a third rotation axis substantially perpendicular to opposing surfaces of the two units facing to each other when the two units are folded with respect to each other, and coupled with the second unit so that the second rotating member and the second unit can be rotated together about the third rotation axis.

The coupling device may further comprise a hinge device for connecting the first and second supporting bodies to each other so that they can be relatively rotated about the first rotation axis.

In the coupling device, the hinge device may comprise a first connection member rotated together with the first unit about the first rotation axis; a second connection member rotated together with the second unit about the first rotation axis and linearly moving along the first rotation axis; and a resilient member for applying a force so that the first and second connection members can be brought into contact with each other, wherein one of the first and second connection members is provided with a cam surface, and the other is provided with a cam follower portion cooperating with the cam surface.

In the coupling device, the cam surface may comprise a first ridge portion including a peak, a second ridge portion including anther peak that is higher than the peak of the first ridge portion, and a cam profile of a peak—including range of the first ridge portion is substantially identical with that of the second ridge portion; and the cam follower portion may have a first cam follower protrusion cooperating with the first ridge portion, and a second cam follower protrusion cooperating with the second ridge portion.

In the coupling device, each of the first and second ridge portions may have two slanted surfaces declined at both sides of the peak thereof. The coupling device may further comprise an insertion groove into which the first cam follower protrusion is inserted, between the first and second ridge portions. In the coupling device, the interval between the insertion groove and a distal end of the slanted surface of the first ridge portion positioned at a side opposite to the insertion groove may be equal to or greater than 180 degrees. In the coupling device, the first ridge portion may further have a horizontal plane connected to one of the two slanted surfaces to cause the second connection member to be maintained at a predetermined position.

The coupling device may further comprise a housing for containing the second connection member and the resilient member. In the coupling device, one of the first rotating member and the first supporting body may have a locking member capable of radially moving with respect to the second rotation axis, and a resilient member for pushing the locking member, and the other may have a locking groove formed to catch the locking member therein. The resilient member urges the locking member toward the locking groove. One of the second rotating member and the second supporting body may have a locking member capable of radially moving with respect to the third rotation axis, and a resilient member for pushing the locking member, and the other may have a locking groove formed to catch the locking member therein. The resilient member urges the locking member toward the locking groove.

In the coupling device, two or more locking grooves may be provided and two adjacent locking grooves may be arranged at an angular interval of 90 degrees. The coupling device may further comprise a fixing member coupled with the rotating member so that the rotating member can be rotated about the second or third rotation axis and fixed to the support member so that the support member and the fixing member can be rotated together; and a resilient member for applying a rotational force to the rotating member. When the rotating member is positioned at a first or a second rotated position, the resilient member exerts a force to prevent the rotating member from being rotated toward another rotated position.

In the coupling device, a third rotated position may be further provided between the first and second rotated positions. If the rotating member is positioned between the first and third rotated positions, the resilient member exerts a force so that the rotating member can be moved toward the first rotated position. If the rotating member is positioned between the third and second rotated positions, the resilient member exerts a force so that the rotating member can be moved toward the second rotated position.

In the coupling device, the resilient member may be a linear member, and the rotating member may have a contact portion that is in contact with the resilient member and deform the resilient member as the rotating member is rotated about the rotation axis. In the coupling device, two resilient members may be arranged to be symmetric with respect to a line, and the contact portion may cause the two resilient members to be moved closer to or far away from each other as the rotating member is rotated. In the coupling device, the two resilient members may be provided with curved portions that come into contact with the contact portion of the rotating member. In the coupling device, the curved portions of the two resilient members may be formed to be closer to each other as they approach central portions thereof. In the coupling device, the rotating member, the fixing member and the resilient member may form a single rotating hinge.

Another aspect of the present invention provides a portable apparatus comprising a first unit, a second unit; and the aforementioned coupling device for coupling the first and second units with each other so that the first and second units can be folded or unfolded with respect to each other.

Since the coupling device for coupling the two units of the portable apparatus so that they can be folded or unfolded with respect to each other can be rotated with respect to the portable apparatus, the two units of the portable apparatus can be folded or unfolded in two different directions, thereby ensuring more convenient use of the portable apparatus. Further, since the hinge device provided in the coupling device can be operated such that the two units may be unfolded by 180 degrees, the portable apparatus can be used more conveniently. Since the unit provided with the liquid crystal display can be rotated independently, the liquid crystal display can be controlled for use in a desired direction such as a horizontal or a vertical direction.

### DESCRIPTION OF THE DRAWINGS

FIGS. 1 (a) and (b) are exploded perspective views of a folder-type portable telephone according to an embodiment of the present invention.

FIG. 2 is an exploded perspective view of the coupling device shown in FIG. 1.

FIG. 3 is a plan view of the coupling device shown in FIG. 1.

FIG. 4 is a sectional view of the coupling device of FIG. 3 taken along line A-A′.

FIGS. 5 (a), (b) and (c) are exploded perspective views of the hinge device shown in FIG. 2.

FIG. 6 is a sectional view of the hinge device shown in FIG. 2.

FIGS. 7 (a) to (d) are views showing a cam surface of the hinge device of FIG. 1 in a deployed state together with corresponding cam follower protrusions, sequentially illustrating the operations of the hinge device.

FIGS. 8 (a) to (f) are views showing usage examples of the folder-type portable telephone shown in FIG. 1.

FIGS. 9 (a) to (c) are views showing sequential rotating states of a first rotating member in a first supporting body of the coupling device shown in FIG. 3.

FIGS. 10 (a) and (b) are exploded perspective views of a folder-type portable telephone according to an embodiment of the present invention.

FIG. 11 is exploded perspective views of a rotating hinge shown in FIG. 10.

FIG. 12 is a plan view of the folder-type portable telephone shown in FIG. 10 in an assembled state.

FIGS. 13 (a) to (c) are views showing usage examples of the folder-type portable telephone shown in FIG. 12 when a coupling device of the folder-type portable telephone is positioned at P1.

FIGS. 14 (a) and (b) are views showing usage examples of the folder-type portable telephone shown in FIG. 12 when the coupling device of the folder-type portable telephone is positioned at P2.

FIGS. 15 (a) to (c) are plan views showing sequential operations of the rotating hinge shown in FIG. 11.

### DETAILED DESCRIPTION OF EMBODIMENTS

Hereinafter, embodiments of the present invention will be described in detail with reference to the accompanying drawings.

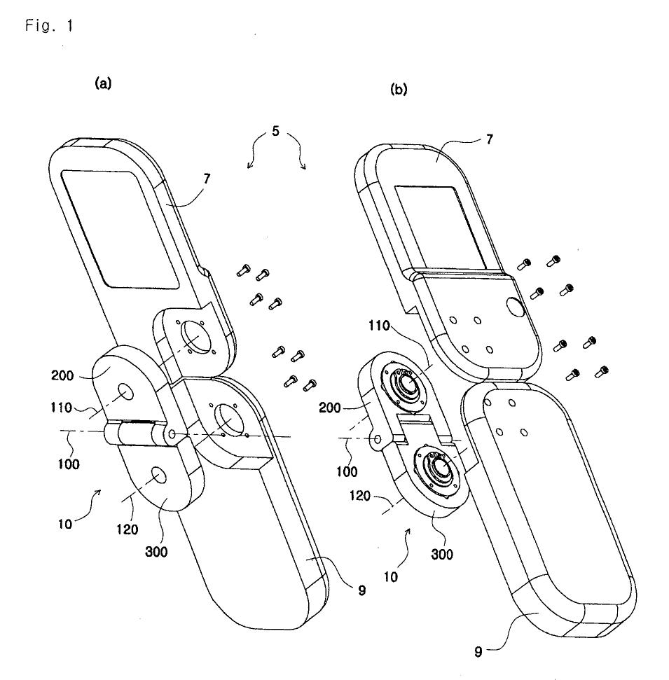

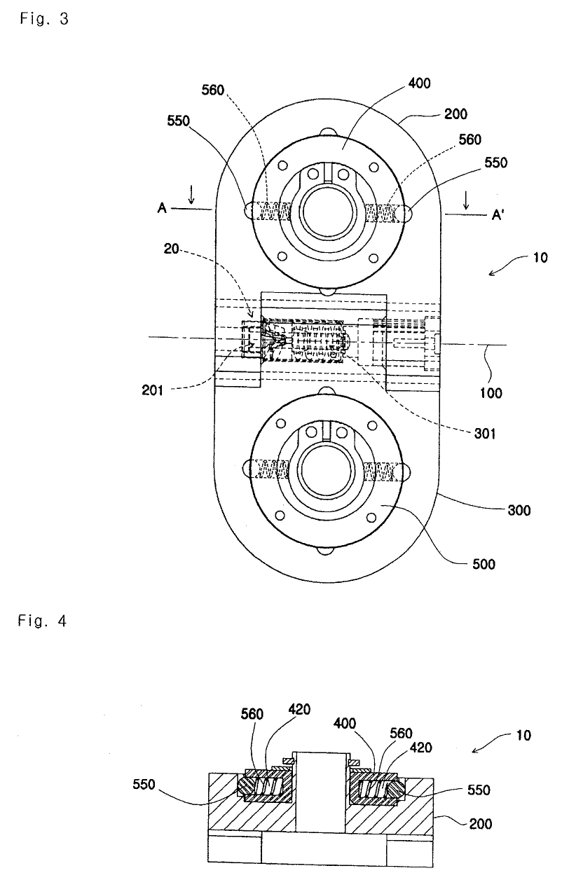

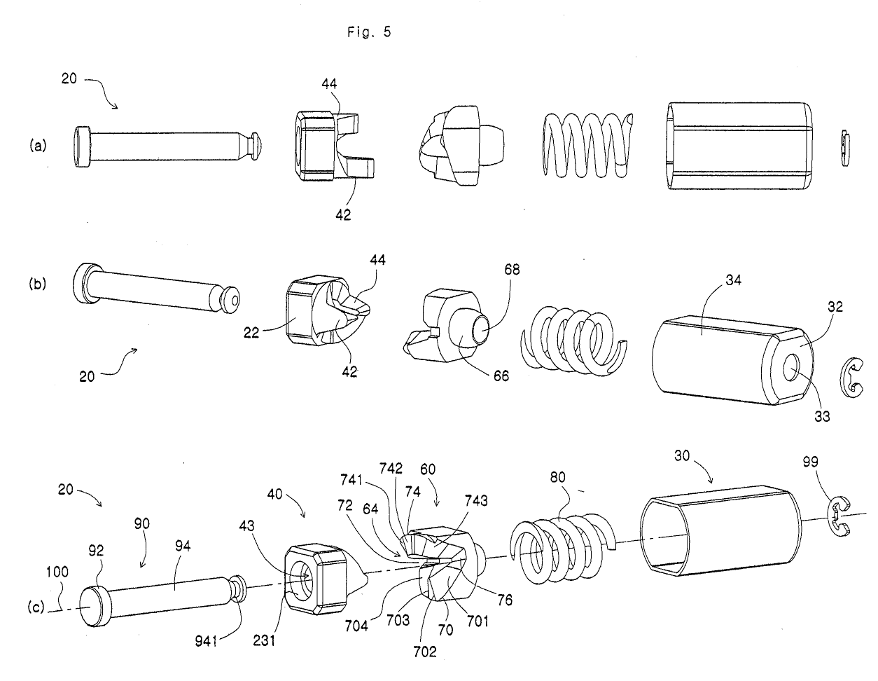

FIGS. 1 to 8 are views of an embodiment of the present invention. Referring to FIG. 1, a portable telephone 5 comprises a first unit 7 provided with a liquid crystal display, and a second unit 9 provided with a keypad (not shown). The first and second units 7 and 9 are coupled with each other by means of a coupling device 10 so that they can be moved to folded and unfolded positions. Referring to FIGS. 1 to 3, the coupling device 10 comprises a first supporting body 200, a second supporting body 300, a first rotating member 400, a second rotating member 500, and a hinge device 20. The first supporting body 200 and the second supporting body 300 are connected to each other by means of the hinge device 20 so that they can be relatively rotated about a first rotation axis 100. A coupling portion 22 of the hinge device 20, which will be described later, is inserted into a coupling hole 201 of the first supporting body 200. A housing 30 of the hinge device 20, which will be described later, is inserted into a mounting hole 301 of the second supporting body 300. The shape of the coupling hole 201 substantially corresponds to that of the coupling portion 22 and the size of the coupling hole 201 is determined such that the coupling portion 22 can be tightly fitted thereinto, thereby enabling the first supporting body 200 and the coupling portion 22 to be rotated together. The shape of the mounting hole 301 substantially corresponds to that of the housing 30 and the size of the mounting hole 301 is determined such that the housing 30 can be tightly fitted into the mounting hole 301, thereby enabling the second supporting body 300 and the housing 30 to be rotated together.

The first and second supporting bodies 200 and 300 have shapes substantially symmetrical with respect to the first rotation axis 100 and comprise first and second receiving portions 600 and 700, which are formed by circularly and inwardly hollowing out the first and second supporting bodies 200 and 300 to receive the first and second rotating members 400 and 500 therein, respectively. Central portions of the first and second receiving portions 600 and 700 are provided with first and second coupling posts 210 and 310 erected along second and third rotation axes 110 and 120, respectively. Annular grooves 211 and 311 are formed along peripheries of end portions of the two coupling posts 210 and 310, respectively. Coupling rings 490 and 590 that will be described later are inserted into the annular grooves 211 and 311, respectively. The second rotation axis 110 extends perpendicularly to a surface of the first unit 7 that faces the second unit 9 when the portable telephone 5 is completely folded. Further, the third rotation axis 120 extends perpendicularly to a surface of the second unit 9 that faces the first unit 7 when the portable telephone 5 is completely folded. Inner walls 610 and 710 of the first and second receiving portions 600 and 700 are provided with locking grooves 220 and 320 positioned at an interval of 90 degrees, respectively. Locking members 550 and 650 that will be described later can be inserted such that they may be locked in the locking grooves 220 and 320, respectively.

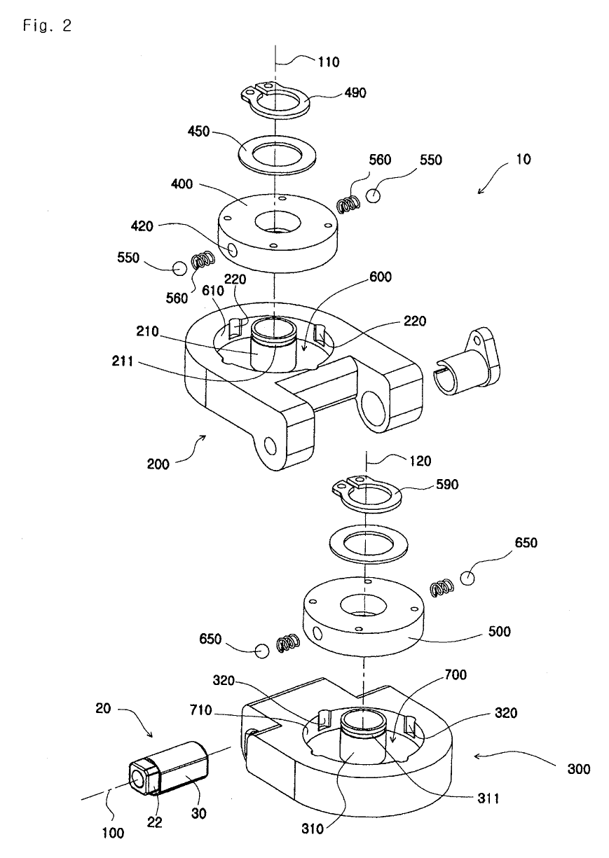

Referring to FIGS. 2 to 4, the first rotating member 400 is ring-shaped to be received in the receiving portion 600 of the first supporting body 200 so that the first rotating member can be rotated about the second rotation axis 110. An outer peripheral surface of the first rotating member 400 faces the inner wall 610 of the receiving portion 600. The outer peripheral surface of the first rotating member 400 is provided with receiving holes 420 that are positioned at an interval of 180 degrees and extend in a radial direction. A resilient member 560, which is a compression coil spring, and the spherical locking member 550 are sequentially inserted into each of the receiving holes 420. A force is exerted on the locking member 550 by means of the resilient member 560 so that the locking member can be moved radially outward from the second rotation axis 110. The locking member 550 may be caught in the locking groove 220 of the receiving portion 600 and may be released by an external force. A washer 450 inserted into the coupling post 210 and a coupling ring 490 coupled with the coupling post 210 prevent the first rotating member 400 from escaping from the receiving portion 600 of the first supporting body 200. The first rotating member 400 and the first unit 7 of the portable telephone 5 are coupled with each other so that they can be rotated together about the second rotation axis 110. Since the structure of the second rotating member 500 is identical with that of the first rotating member 400, a detailed description thereof will be omitted. The second rotating member 500 and the second unit 9 of the portable telephone 5 are coupled with each other so that they can be rotated together about the third rotation axis 120. The coupling device 10 is coupled with a side of the portable telephone 5 that is to be located inside of the portable telephone in the folded state.

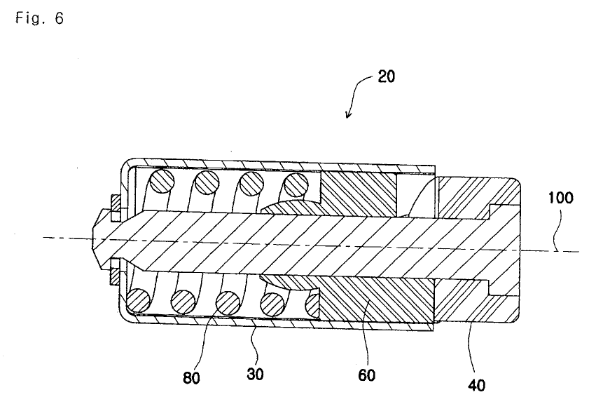

Referring to FIGS. 5 and 6, the hinge device 20 comprises the housing 30, a first connection member or a cam follower member 40, a second connection member or a cam member 60, a resilient member 80, and a guide rod 90. The housing 30 is composed of an elongated hollow cylinder. The longitudinal central axis of the housing 30 becomes the first rotation axis 100. The housing 30 has an end wall 32 formed at a side end thereof, and a sidewall 34 formed by extending from the end wall 32. The other end of the housing 30 opposite to the end wall 32 is open. A central portion of the end wall 32 is provided with a through-hole 33. A distal end of the guide rod 90, which will be described later, protrudes through the through-hole 33 and is engaged with an E-shaped ring 99. The housing 30 and the second supporting body 300 are coupled with each other so that they can be rotated together about the first rotation axis 100.

Referring still to FIGS. 5 and 6, the first connection member 40 comprises a coupling portion 22 and first and second cam follower protrusions 42 and 44 extending from the coupling portion 22. The coupling portion 22 takes the shape of a low-height square post of which edges are substantially chamfered and is provided with a passage hole 43 that centrally penetrates therethrough along the first rotation axis 100. The guide rod 90 to be described later passes through the passage hole 43. An entrance side of the passage hole 43 is countersunk to form a receiving portion 231 for receiving a head 92 of the guide rod 90 to be described later. The first and second cam follower protrusions 42 and 44 are provided at a rear side of the coupling portion 22 and on both of the radially opposite sides with respect to the first rotation axis 100, respectively. The first and second cam follower protrusions 42 and 44 extend in a direction parallel to the first rotation axis 100 toward a cam surface 64 of the second connection member 60 that will be described later. Each of the first and second cam follower protrusions 42 and 44 is tapered with its thickness gradually decreasing toward a rounded distal end thereof. Two distal ends of the first and second cam follower protrusion 42 and 44 cooperate with first and second ridge portions 70 and 74 of the cam surface 64 of the second connection member 60, which will be described later, respectively. To ensure that the distal end of the first cam follower protrusion 42 is positioned toward the second connection member 60 farther than the distal end of the second cam follower protrusion 44, the first cam follower protrusion 42 extends toward the second connection member 60 longer than (i.e., extends from the coupling portion 22 higher than) the second cam follower protrusion 44. The first and second cam follower protrusions 42 and 44 are positioned at an interval of 180 degrees about the first rotation axis 100. The first connection member 40 is inserted through the open end of the housing 30 such that the coupling portion 22 protrudes outside of the housing 30 and the first and second cam follower protrusions 42 and 44 are received inside the housing 30. The first connection member 40 can be rotated with respect to the housing 30 about the first rotation axis 100 by means of the guide rod 90.

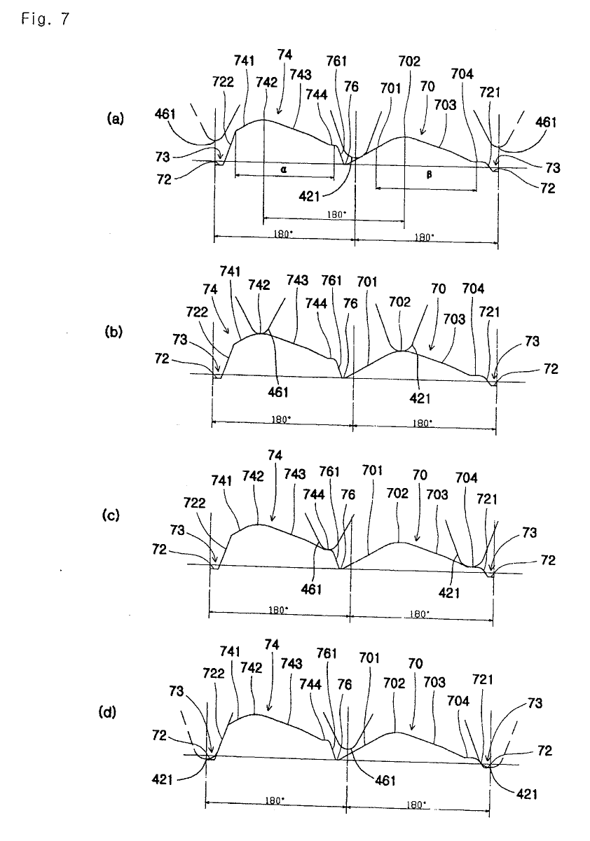

Referring still to FIGS. 5 and 6, the second connection member 60 comprises a sidewall 62, a cam surface 64 formed at a side thereof facing the cam follower member 40, and a cylindrical boss 66 formed by extending from a central portion of the side opposite to the cam surface 64. The second connection member 60 is provided with a through-hole 68 that penetrates therethrough from the cam surface 64 to the boss 66 along the first rotation axis 100. The guide coupling rod 90 passes through the through-hole 68. The second connection member 60 is inserted into the housing 30 so that it can be moved linearly along the first rotation axis 100 but cannot be rotated. The cam surface 64 has the first ridge portion 70, a first valley portion 72, the second ridge portion 74 and a second valley portion 76 which are sequentially positioned clockwise about the first rotation axis 100 when viewed from the first connection member 40. Referring together to FIG. 7 that shows the cam surface 64 in a deployed state, the range of the first ridge portion 70 is formed to be longer than that of the second ridge portion 74. That is, the interval between the first and second valley portions 72 and 76 where the first ridge portion 70 is provided is formed to be larger than 180 degrees about the first rotation axis 100, while the interval between the first and second valley portions 72 and 76 where the second ridge portion 74 is provided is formed to be smaller than 180 degrees about the first rotation axis 100.

Referring to FIGS. 5 and 7, the first ridge portion 70 has a first upward slanted portion 701, a peak 702, a second downward slanted portion 703 and a horizontal plane 704 that are sequentially provided clockwise about the first rotation axis 100 when viewed from the first connection member 40. The second ridge portion 74 has a first upward slanted portion 741, a peak 742, a second downward slanted portion 743 and a horizontal plane 744 that are sequentially provided clockwise about the first rotation axis 100 when viewed from the first connection member 40. The shape (profile) of the second ridge portion 74 is substantially identical with a portion of the first ridge portion 70 including the peak 702. That is, the first slanted portion 741 declined from the peak of the second ridge portion 74 has a slope identical with that of the first slanted portion 701 declined from the peak of the first ridge portion 70, while the extension length of the first slanted portion 741 of the second ridge portion 74 is shorter than that of the first slanted portion 701 of the first ridge portion 70. Similarly, the second slanted portion 743 declined from the peak of the second ridge portion 74 has a slope identical with that of the second slanted portion 703 declined from the peak of the first ridge portion 70, while the extension length of the second slanted portion 743 of the second ridge portion 74 is identical with that of the second slanted portion 703 of the first ridge portion 70. The peak 742 of the second ridge portion 74 is positioned toward the first connection member 40 farther than the peak 702 of the first ridge portion 70 such that the height difference between the peaks is identical with that between the first and second cam follower protrusions 42 and 44 of the first connection member 40. Consequently, the second ridge portion 74 is configured such that remaining parts with the exception of the parts at both ends of the first ridge portion 70 are raised directly. The peak 702 of the first ridge portion 70 and the peak 742 of the second ridge portion 74 are diametrically positioned, i.e., at an interval of 180 degrees about the first rotation axis 100.

The second connection member 60 is inserted through the open end of the housing 30. At this time, the cam surface 64 faces the first and second cam follower protrusions 42 and 44 of the first connection member 40. The second connection member 60 is inserted substantially tightly into the housing 30 so that it can be linearly moved along the first rotation axis 100 but cannot be rotated.

Referring to FIGS. 5 and 6, the resilient member 80 urges the second connection member 60 toward the first connection member 40. The resilient member 80 is preferably a compression coil spring. The boss 66 of the cam member 60 is inserted into one side portion of the resilient member 80.

The guide coupling rod 90 has the head 92 and an elongated cylindrical body 94 extending along the first rotation axis 100 from the head 92. A distal end of the body 94 is provided with an annular coupling groove 941. The head 92 is received in the receiving portion 231 provided at the entrance side of the passage hole 43 of the first connection member 40. The body 94 sequentially passes through the passage hole 43 of the first connection member 40, the penetration hole 68 of the cam member 60 and the interior of the resilient member 80, so that the distal end of the body 94 can protrude to the outside through the through-hole 33 provided in the end wall 32 of the housing 30. At this time, the coupling groove 941 provided at the distal end of the body 94 also protrudes to the outside beyond the end wall 32 of the housing 30 and the stopper ring 99 that is also called an E-shaped ring is engaged with the coupling groove 941 to couple the guide rod 90 with the housing 30. The cam follower member 40 can be rotated about the cylindrical body 94 of the guide rod 90.

Such a configuration of the hinge device 20 causes the first and second supporting bodies 200 and 300 connected by the hinge device 20 to be folded or unfolded within a rotation range of 180 degrees about the first rotation axis 100, and to be automatically unfolded at one side with respect to a reference point in the rotation range and folded at the other side with respect to the reference point. Further, a pre-stop range is formed within a certain range before the first and second supporting bodies 200 and 300 are completely unfolded. This will be described in detail later.

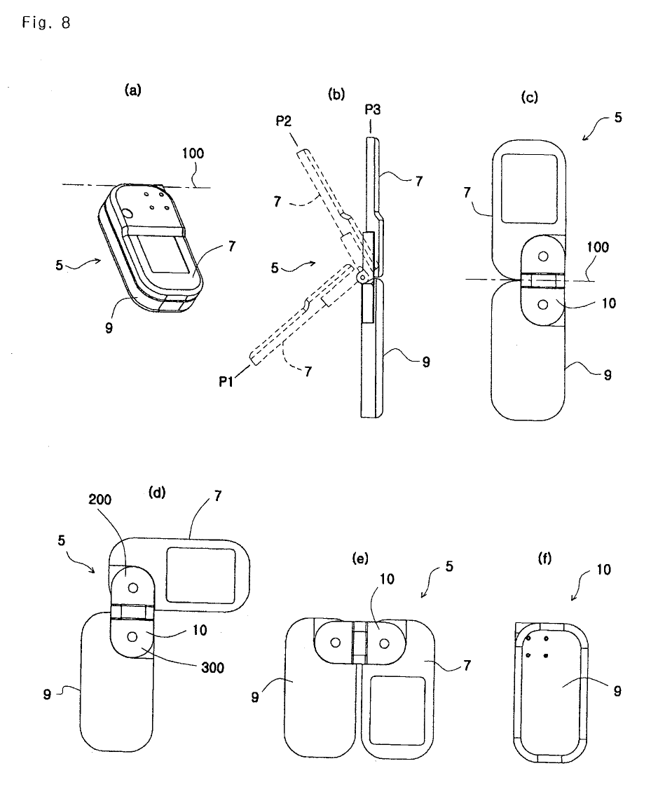

Now, referring to FIGS. 7 and 8, usage examples of the portable telephone and the operation of the coupling device will be described in connection with an embodiment. FIG. 8 (a) shows the portable telephone 5 in a completely folded state. At this time, the first rotation axis 100 is positioned at a longitudinal upper end of the portable telephone 5. At this time, FIG. 7 (a) shows the positions of first and second cam follower portions 421 and 461 on the cam surface 64 of the hinge device 20. Referring to FIG. 7 (a), the first cam follower portion 421 is positioned to be in contact with the first slanted portion of the first ridge portion 70, while the second cam follower portion 461 is positioned to be spaced apart from the first valley portion 72 where an insertion groove 73 is provided. Referring together to FIG. 6, in this state, the cam member 60 urges the cam follower member 40 by means of the force of the resilient member 80. Then, the resilient member 80 and the first slanted 701 cause the cam follower member 40 to receive a rotational force that in turn causes the first unit 7 to be rotated toward the second unit 9. That is, when the portable telephone 5 is completely folded as shown in FIG. 8 (a), the hinge device 20 generates the rotational force for bringing the first and second units 7 and 9 into close contact with each other so that the portable telephone 5 can be stably maintained in the folded state.

In this state, when the first and second units 7 and 9 of the portable telephone 5 are moved far away from each other so that the portable telephone 5 can be unfolded to be used, the first cam follower portion 421 moves upward along the first slanted portion 701 of the first ridge portion 70, and the second cam follower portion 461 reaches the first slanted portion 741 of the second ridge portion 74 and then moves upward in contact with and along the first slanted portion 741. When the first and second units 7 and 9 are further moved far away from each other, the first and second cam follower portions 421 and 461 move upward along the first slanted portion 701 of the first ridge portion 70 and the second slanted portion 741 of the second ridge portion 74, respectively, and then reach the peak 702 of the first ridge portion 70 and the peak 742 of the second ridge portion 74, respectively. This corresponds to a state where the first case unit 7 is located at position P1 as shown in FIG. 8 (b). If an external force for moving the first and second units 7 and 9 of the portable telephone 5 far away from each other is removed before the first and second cam follower portions 421 and 461 reach the peaks 702 and 742, respectively, the resilient member 80 that urges the cam member 60 toward the cam follower member 40 causes the first and second cam follower portions 421 and 461 to move along the first and second slanted portions 701 and 741 of the first and second ridge portions 70 and 74, respectively, thereby automatically folding the portable telephone 5 again.

If the first and second units 7 and 9 of the portable telephone 5 are still further moved far away from each other, the first and second cam follower portions 421 and 461 are positioned on the second slanted portion 703 of the first ridge portion 70 and the second slanted portion 743 of the second ridge portion 74, respectively. In this state, since the resilient member 80 urges the cam member 60 toward the cam follower member 40, the first and second cam follower portions 421 and 461 move downward along the second slanted portion 703 of the first ridge portion 70 and the second slanted portion 743 of the second ridge portion 74 even without an external force, respectively, and then reach boundary parts of the second slanted portion 703 of the first ridge portion 70 and the second slanted portion 743 of the second ridge portion 74, respectively. This corresponds to a state where the first case unit 7 is located at a position P2 as shown in FIG. 8 (b).

To further move the first case unit 7 from position P2, an external rotational force should be exerted thereon continuously. If the exertion of the rotational force is stopped intermediately, the first case unit 7 stops and is maintained at that position by the force of the resilient member 80. At this time, the first and second cam follower portions 421 and 461 of the cam follower member 40 are positioned at certain positions on the horizontal plane 704 of the first ridge portion 70 and the horizontal plane 744 of the second ridge portion 74, respectively. Since the horizontal plane 744 of the second ridge portion 74 is shorter than the horizontal plane 704 of the first ridge portion 70, the second cam follower portion 461 is separated from the horizontal plane 744 of the second ridge portion 74 prior to separation of the first cam follower portion 421 if the second case unit 9 continues to be moved. In this state, when the first case unit 7 is still further moved, the first cam follower portion 421 passes by a first connection slanted surface 721 and is inserted into and fixed in the insertion groove 73 so that the first case unit 7 can be positioned at position P3 as shown in FIG. 8 (b) and thus the first and second units 7 and 9 can be unfolded at an angle of 180 degrees. A plan view of the portable telephone 5 in this state is shown in FIG. 8 (c).

Now, the operation of the hinge device 20 will be described when the portable telephone is changed from the unfolded state to the folded state. That is, the process of changing the portable telephone from the state shown in FIG. 8 (c) to the state shown in FIG. 8 (a) will be described. The state where the portable telephone 5 is completely unfolded (at position P3 shown in FIG. 8 (b)) is the state where the first cam follower portion 421 is inserted into and fixed in the insertion groove 73. To fold the portable telephone 5 in this state, a rotational force should be exerted thereon until it reaches position P2 shown in FIG. 8 (b). If a force exceeding a predetermined value is applied in the fixed state, the first cam follower portion 421 moves upward along the first connection slanted surface 721 to reach the horizontal plane 704 since the first connection slanted surface 721 is provided around the insertion groove 73. If the portable telephone 5 continues to be folded, the second cam follower portion 461, which has been separated from the cam surface, subsequently reaches the horizontal plane 744 of the second ridge portion 74. Since the first and second cam follower portions 421 and 461 pass by the horizontal planes 704 and 744 until they reach the state shown in FIG. 5 (c), i.e., position P2 shown in FIG. 8 (b), they can be rotated with a constant rotational force. However, a larger rotational force is required from position P2 to position P1 shown in FIG. 8 (b) since the first and second cam follower portions 421 and 461 pass by the second upward slanted portion 703 of the first ridge portion 70 and the second upward slanted portion 743 of the second ridge portion 74, respectively. After the first and second cam follower portions 421 and 461 have passed by the peak 702 of the first ridge portion 70 and the peak 742 of the second ridge portion 74, respectively, they pass by the first downward slanted portions 701 and 741. Thus, the units can be automatically rotated so that the portable telephone 5 can be folded without an external rotational force. If the external force for folding the portable telephone 5 is removed before the first and second cam follower portions 421 and 461 reach the peaks 702 and 742, the resilient member 80 that urges the second connection member 60 toward the cam follower member first connection member 40 causes the first and second cam follower portions 421 and 461 to move along the second slanted portions 703 and 743 of the first and second ridge portions 70 and 74, respectively, thereby automatically unfolding the portable telephone 5 again.

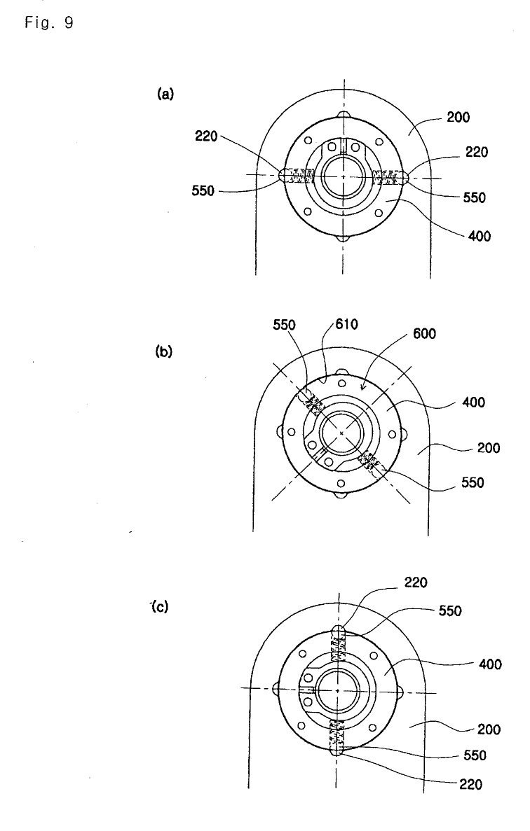

FIG. 9(a) shows the state of the first rotating member 400, which has been coupled with the first unit 7, within the first supporting body 200 of the coupling device 10 at a state where the first and second units 7 and 9 of the portable telephone 5 are completely unfolded as shown in FIG. 8 (c). Referring to FIG. 9 (a), the locking member 550 is inserted into the locking groove 220 of the first supporting body 200 so that the first rotating member 400 can be fixed. In this state, if the first unit 7 is rotated about the second rotation axis 110 with respect to the first supporting body 200 by applying a sufficient rotational force thereto, the locking member 550 escapes from the locking groove 220. If the first unit 7 is further rotated, the locking member 550 is rotated while being in close contact with the inner wall 610 of the first receiving portion 600 as shown in FIG. 9 (b). In this state, if the rotational force continues to be applied so that the locking member 550 can be rotated by 90 degrees, the locking member 550 is inserted into and fixed in the locking groove 220 as shown in FIG. 9 (c). The state of the portable telephone 5 at this time is shown in FIG. 8 (d). In this state, if the second unit 9 is rotated about the third rotation axis 120 with respect to the second supporting body 300 of the coupling device 10, the first unit 7 can be positioned beside the second unit 9 as shown in FIG. 8 (e). If the second unit 9 is moved toward the first unit 7 in the state shown in FIG. 8 (e), the portable telephone 5 is completely folded by the operation of the hinge device 20 as shown in FIG. 8 (f).

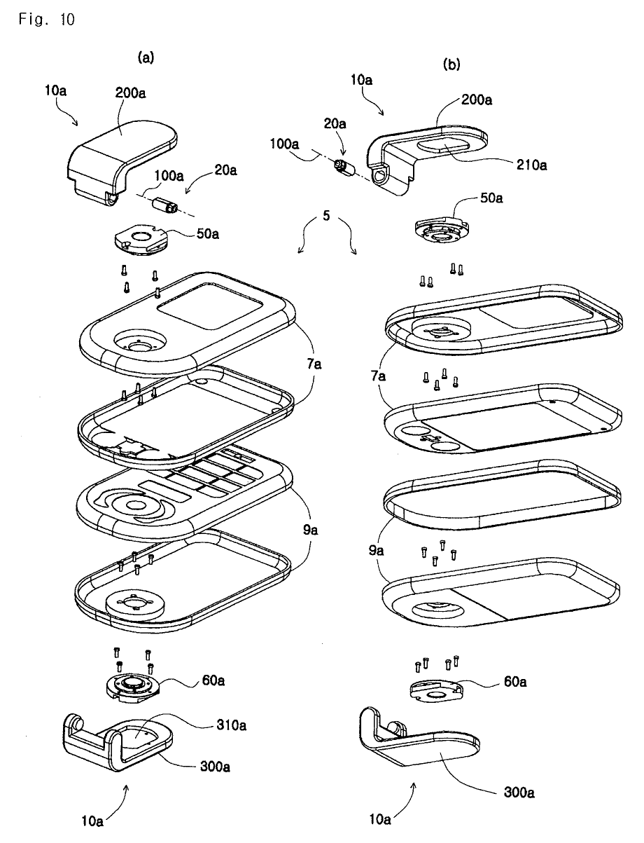

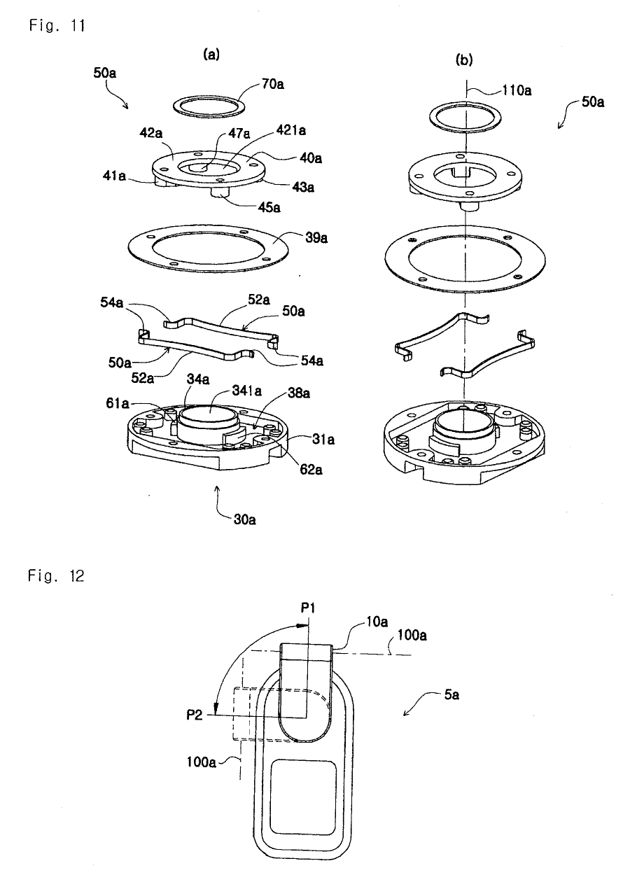

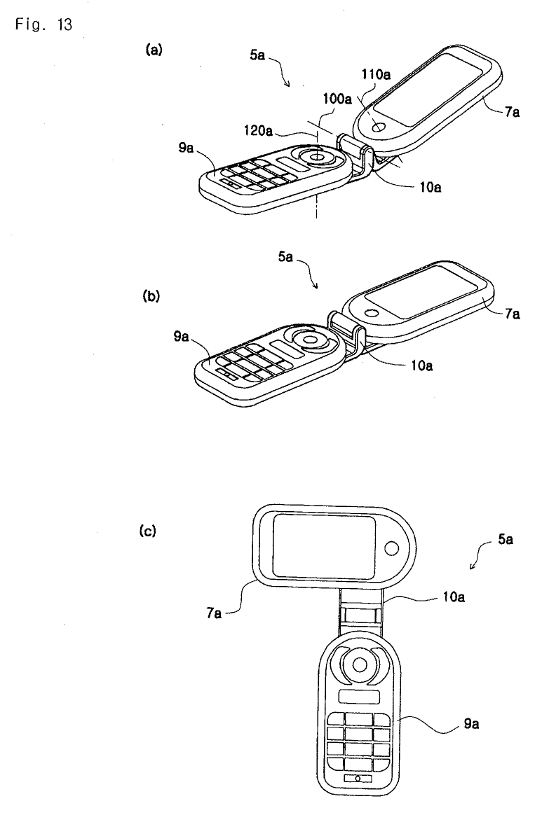

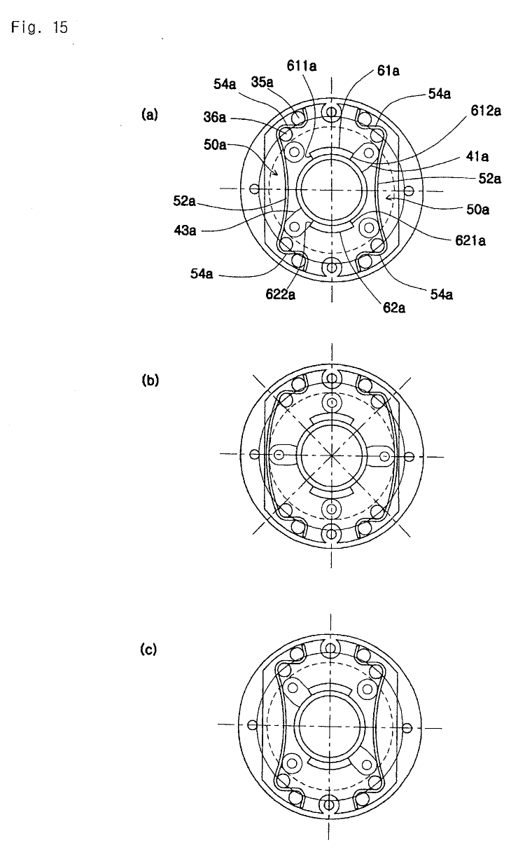

FIGS. 10 to 15 show an embodiment of the present invention. Referring to FIG. 10, a portable telephone 5a comprises a first unit 7a provided with a liquid crystal display and a second unit 9a provided with a keypad. The first and second units 7a and 9a are coupled with each other by means of a coupling device 10a. The coupling device 10a comprises a first supporting body 200a, a second supporting body 300a, a first rotating hinge 50a, a second rotating hinge 60a, and a first hinge device 20a. The first supporting body 200a and the second supporting body 300a are connected to each other by means of the hinge device 20a so that they can be relatively rotated about a first rotation axis 100a. Since the configuration and operation of the hinge device 20a are the same as the hinge device shown in FIGS. 5 to 7, a detailed description thereof will be omitted. The first supporting body 200a and the second supporting body 300a are provided with seating grooves 210a and 310a in which the first and second rotating hinges 50a and 60a are seated, respectively. Referring to FIGS. 10 and 11, the first rotating hinge 50a comprises a first fixing member 30a, a first rotating member 40a, two resilient members 50a, and a coupling ring 70a. Referring to FIGS. 11 and 15, the fixing member 30a has a body 31a and a cover 39a for covering the body 31a. The body 31a takes the shape of a disk and is provided therein with a receiving space 38a excavated to receive the two resilient members 50a. A central portion of the receiving space 38a is provided with a coupling post 34a with a through-hole 341a, and the coupling ring 70a is inserted around a distal end of the coupling post 34a at a final assembly stage. Locking protrusions 61a and 62a are formed to protrude at both sides of a base portion of the coupling post 34a, respectively. First and second contact portions 41a and 43a of the first rotating member 40a, which will be described later, are brought into contact with and caught by both circumferential ends 611a, 612a, 621a and 622a of the locking protrusions 61a and 62a. There are pairs of locking at four positions in the receiving space 38a so that locking portions 54a of each of the two resilient members 50a can be fitted around the corresponding locking posts. Each pair of locking posts comprises first and second adjacent locking posts 35a and 36a. The cover 39a generally takes the shape of a ring with a circular hole (sized such that protrusions 41a, 43a, 45a and 47a of the first rotating member 40a can be inserted into and rotated in the hole) at the center thereof and covers the receiving space 38a of the body 31a. The first fixing member 30a is inserted into and engaged with the seating groove 210a so that the first fixing member 30a can be rotated together with the first supporting body 200a of the coupling device 10a about the second rotation axis (110a in FIG. 12).

The first rotating member 40a has a circular coupling plate 42a to be coupled with the first unit 7a of the portable telephone 5a; and the first contact portion 41a, a first internally threaded post 45a, the second contact portion 43a and a second internally threaded post 47a, which protrude from the coupling plate 42a and are sequentially and equidistantly arranged in a circumferential direction. A passage 421a is provided at a central portion of the coupling plate 42a. The coupling post 34a of the first fixing member 30a is inserted through the passage 421a so that the first rotating member 40a can be rotated about the second rotation axis 110a while being guided by the coupling post 34a. The first and second contact portions 41a and 43a have symmetrical shapes with respect to the second rotation axis 110a and extend radially outward from the central passage 421a. Radial ends of the first and second contact portions 41a and 43a are rounded and come into contact with curved portions 52a of the two resilient members 50a, which will be described later. When the first rotating member 40a is rotated with respect to the first fixing member 30a, the first and second contact portions 41a and 43a can be caught by the two locking protrusions 61a and 62a of the first fixing member 30a, respectively. Accordingly, there is a limitation on the rotational range of the first rotating member 40a. The first rotating member 40a and the first unit 7a of the portable telephone 5a are coupled with each other so that they can be rotated together about the second rotation axis 110a.

Referring to FIGS. 11 and 15, the two resilient members 50a are identical linear members, and each of the resilient members has the central curved portion 52a with an arc shape and the locking portions 54a at both ends thereof. The locking portion 54a is formed by being bent toward one side from the curved portion 52a and subsequently bent toward an opposite side after slight extension. The locking portion 54a is caught by the two locking posts 35a and 36a while being wrapped around the locking posts. The curved portions 52a of the two resilient members 50a become closer to each other as they approach central portions thereof. The curved portions 52a of the two resilient members 50a are in contact with arcs of radial distal ends of the first and second contract portions 41a and 43a of the first rotating member 40a, respectively, thereby providing a rotational force to the first rotating member 40a. When the first rotating member 40a is positioned either at a first rotated position (FIG. 9 (a)) or at a second rotated position (FIG. 9 (c)), the two resilient members 50a exert forces that prevent the first rotating member 40a from being rotated toward other rotated positions. The state shown in FIG. 9 (b) is a neutral state in which the rotating member 40a is located at a third rotated position. If the rotating member 40a is positioned between the first rotated position and the third rotated position, the resilient members 50a exert forces so that the rotating member 40a can be rotated toward the first rotated position. If the rotating member 40a is positioned between the third rotated position and the second rotated position, the resilient member 50a exert forces so that the rotating member 40a can be rotated toward the second rotated position.

Since the configuration of the second rotating hinge 60a is the same as the first rotating hinge 50a, a detailed description thereof will be omitted. The second rotating hinge 60a is operated to rotate the second supporting body 300a of the coupling device 10a and the second unit 9a of the portable telephone 5a about a third rotation axis (120a in FIG. 13 (a)).

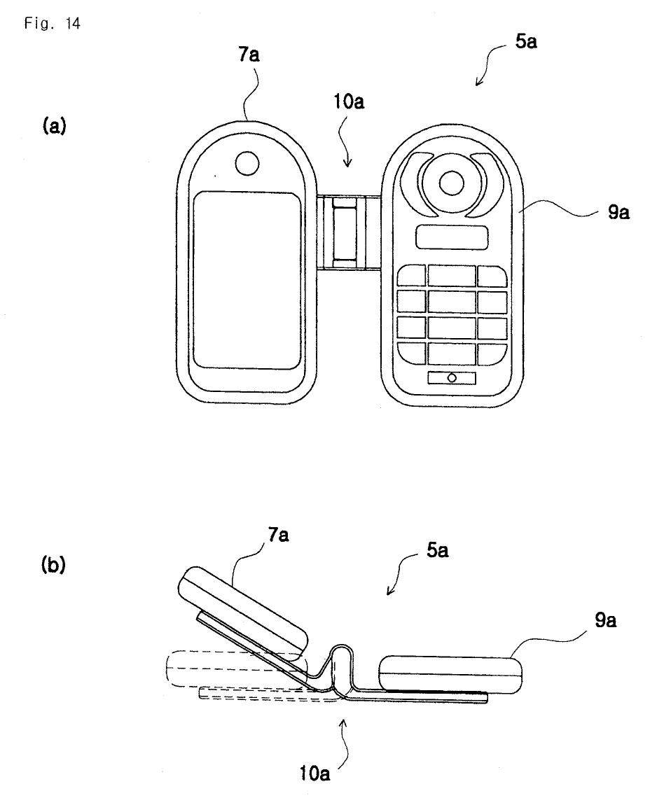

FIGS. 12 to 14 show usage examples of the portable telephone 5a shown in FIG. 10. Referring to FIG. 12, the coupling device 10a may be positioned either at position P1 or position P2. At position P1, the first rotation axis 100a is positioned at a longitudinal upper side of the portable telephone 5a, whereas at position P2, the first rotation axis 100a is positioned at a lateral side of the portable telephone 5a. If the portable telephone 5a is positioned at position P1, the portable telephone 5 can be used while being folded or unfolded as shown in FIG. 13. If the portable telephone 5a is positioned at position P2, the portable telephone 5a can be used while being folded or unfolded as shown in FIG. 14.

Although embodiments of the present invention has been described, it can be understood by those skilled in the art that various modifications and changes can be made thereto without departing from the scope and spirit of the present invention, and that such modifications and changes also fall within the scope of the present invention.

What is claimed is:

1. A portable electronic device, comprising:
a first panel;
a second panel; and
a connector connecting the first panel and second panel, the connector comprising a first piece and a second piece connected to the first piece, wherein the second piece is rotatable relative to the first piece about a first axis,
wherein the first piece is connected to the first panel, the first panel being rotatable relative to the first piece about a second axis,
wherein the second piece is connected to the second panel, the second panel being rotatable relative to the second piece about a third axis.

2. The device of claim 1, wherein the second piece is connected to the second panel such that the second panel is rotatable relative to the first piece about the first axis.

3. The device of claim 1, wherein at least one of the second axis and the third second axis is substantially perpendicular to the first axis.

4. The device of claim 1, wherein the connector is configured to enable the first and second panels to move relative to each other between a folded configuration and a first unfolded configuration and further between the first unfolded configuration and a second unfolded configuration, wherein between the first and second unfolded configurations, at least one of the first and second panels is configured to rotate about the second or third axis.

5. The device of claim 4, wherein between the first and second unfolded configurations, both the first and second panels are configured to rotate about the second or third axis.

6. The device of claim 4, wherein in the folded configuration, the second axis substantially overlaps with the third axis, wherein the connector is further configured to allow the first panel to rotate about the second axis relative to the connector from the folded configuration.

7. The device of claim 4, wherein in the folded configuration, the first and second pieces are overlapping with each other, wherein the connector is further configured to allow the first piece and second piece rotate about the second axis relative to each other.

8. The device of claim 4, wherein the first panel comprises a substantially flat display surface for displaying information thereon, wherein the second panel comprises a substantially flat input surface comprising a plurality of buttons for inputting alphanumeric information therethrough, wherein in the folded configuration, the display surface and the input surface face each other.

9. The device of claim 8, wherein the first panel comprises a first edge extending generally straight, and the second panel comprises a second edge extending generally straight, wherein in the folded configuration the first edge and the second edge are generally overlapping when viewed away from the device in a direction perpendicular to the display surface, wherein in the first unfolded configuration, the first edge and the second edge extend generally in the same direction without overlapping when viewed away from the device in the direction perpendicular to the display surface.

10. The device of claim 9, wherein in the second unfolded configuration, the first edge and second edge extend generally in the same direction opposing each other when viewed away from the device in the direction perpendicular to the display surface.

11. The device of claim 1, wherein the third axis is substantially parallel to the second axis.

12. The device of claim 1, wherein the third axis is substantially nonparallel to the second axis.

13. The device of claim 1, wherein the first panel comprises a first surface, wherein the second panel comprises a second surface, wherein the first and second surfaces opposes each other in the folded configuration, wherein in the first unfolded configuration, the first and second surfaces form an angle therebetween from about 120° to about 200°.

14. The device of claim 1, wherein the portable device comprises a handheld electronic device.

15. A method of changing configurations of a portable electronic device, comprising:
providing the portable electronic device of claim 1, the device comprising a first panel, a second panel and a connector interconnecting the first and second panels;
moving the first and second panels relative to each other between a folded configuration and a first unfolded configuration; and
moving the first and second panels relative to each other between the first unfolded configuration and a second unfolded configuration.

16. A portable electronic device, comprising:
a first panel;
a second panel; and
a first hinge configured to enable the first and second panels to move relative to each other between a folded configuration and a first unfolded configuration;
a second hinge configured to enable the first and second panels to move relative to each other between the first unfolded configuration and a second unfolded configuration; and
a third hinge configured to enable the first and second panels to move relative to each other between the second unfolded configuration and a third unfolded configuration.

17. The device of claim 16, wherein the first, second and third hinges form a self-contained connector.

18. The device of claim 17, wherein the connector comprises a first piece and a second piece connected to the first piece, wherein the first hinge is configured to enable to move the first piece and the second piece with respect to each other.

19. The device of claim 16, wherein the first panel comprises a substantially flat display surface for displaying information thereon, wherein the second panel comprises a substantially flat input surface comprising a plurality of buttons for inputting alphanumeric information therethrough, wherein in the folded configuration, the display surface and the input surface face each other.

20. The device of claim 19, wherein in the folded configuration, the display surface and the input surface form therebetween an angle, which is substantially equal to 0°.

21. The device of claim 19, wherein in the first unfolded configuration, the display surface and the input surface form an angle therebetween, which is from about from about 120° to about 200°.

22. The device of claim 19, wherein in the first and second unfolded configurations, the display surface and the input surface form an angle therebetween, which is from about 120° to about 200°.

23. The device of claim 19, wherein the first panel comprises a first edge extending generally straight, and the second panel comprises a second edge extending generally straight, wherein in the folded configuration the first edge and the second edge are generally overlapping, wherein in the first unfolded configuration, the first edge and the second edge extend generally in the same direction without overlapping when viewed away from the device in a direction perpendicular to the display surface.

24. The device of claim 23, wherein in the third unfolded configuration, the first edge and second edge extend generally in the same direction opposing each other when viewed away from the device in the direction perpendicular to the display surface.

25. The device of claim 19, wherein the first panel comprises a first edge extending generally straight, and the second panel comprises a second edge extending generally straight, wherein in the folded configuration the first edge and the second edge are generally overlapping, wherein in the first unfolded configuration, the first edge and the second edge form therebetween a first angle of about 160° to about 200°, when viewed away from the device in the direction perpendicular to the display surface.

26. The device of claim 25, wherein in the third unfolded configuration, the first edge and the second edge form therebetween a third angle of 0° to about 90°, when viewed away from the device in the direction perpendicular to the display surface.

27. The device of claim 26, wherein in the second unfolded configuration, the first edge and the second edge form therebetween a second angle between the first and second angle, when viewed away from the device in the direction perpendicular to the display surface.
